(19) United States
(12) Patent Application Publication
(10) Pub. No.: US 2022/0060174 A1
(43) Pub. Date: Feb. 24, 2022

(54) BAW RESONATOR WITH IMPROVED PERFORMANCE

(71) Applicant: RF360 EUROPE GMBH, Munich (DE)

(72) Inventor: Thomas Bain POLLARD, Longwood, FL (US)

(21) Appl. No.: 17/408,048

(22) Filed: Aug. 20, 2021

Related U.S. Application Data
(60) Provisional application No. 63/068,719, filed on Aug. 21, 2020.

(51) Int. Cl. H03H 9/17; H03H 9/02; H03H 9/56; H03H 9/13

(52) U.S. Cl. CPC H03H 9/175; H03H 9/131; H03H 9/568; H03H 9/02015

(57) ABSTRACT

Aspects of the disclosure relate BAW resonator with improved performance, RF-filter. A BAW resonator with improved performance is provided. The resonator includes a piezoelectric material sandwiched between a first electrode and a second electrode. The piezoelectric material is provided as a monocrystalline material having a particular orientation defined by a particular Euler angle such as the piezoelectric material being LiTaO₃ and having an orientation with Euler angles selected from [0°±5°; 130°±15°; n°±5°], or a symmetrical equivalent.

### CLAIM OF PRIORITY UNDER 35 U.S.C. § 119

The present application for patent claims priority to Provisional Application No. 63/068,719 entitled “BAW RESONATOR WITH IMPROVED PERFORMANCE” filed Aug. 21, 2020 and assigned to the assignee hereof and hereby expressly incorporated by reference herein in its entirety.

### FIELD

The present disclosure relates generally to BAW resonators with improved performance and particularly to BAW resonators with increased fractional bandwidth desirable for new 5G bands and to corresponding filters.

### BACKGROUND

Wireless communication transceivers used in electronic devices generally include multiple radio frequency (RF) filters for filtering a signal for a particular frequency or range of frequencies. Electroacoustic devices (e.g., “acoustic filters”) are used for filtering high-frequency (e.g., generally greater than 100 MHz) signals in many applications. Using a piezoelectric material as a vibrating medium, acoustic resonators operate by transforming an electrical signal wave that is propagating along an electrical conductor into an acoustic wave that is propagating via the piezoelectric material. The acoustic wave propagates at a velocity having a magnitude that is significantly less than that of the propagation velocity of the electromagnetic wave. Generally, the magnitude of the propagation velocity of a wave is proportional to a size of a wavelength of the wave. Consequently, after conversion of an electrical signal into an acoustic signal, the wavelength of the acoustic signal wave is significantly smaller than the wavelength of the electrical signal wave. The resulting smaller wavelength of the acoustic signal enables filtering to be performed using a smaller filter device. This permits acoustic resonators to be used in electronic devices having size constraints, such as portable electronic devices).

BAW resonators (BAW=bulk acoustic wave) can be used in RF-filters (e.g. in a ladder-type like circuit topology or in a lattice-type like circuit topology) to select—e.g. in mobile communication systems—wanted RF signals from unwanted RF signals. BAW resonators include a piezoelectric material between a bottom electrode and a top electrode. Due to the piezoelectric effect, the BAW resonator can convert between electromagnetic RF signals and acoustic RF signals.

Some parameters that determine the performance of a BAW resonator are the electromechanical coupling coefficient κ², achievable working frequencies such as a resonance frequency and an anti-resonance frequency, the resonator's quality factor, losses, and the like.

New frequency bands for future communication systems such as hardware for the fifth generation (new radio) (5G NR) creates a demand for filters with an increased fractional bandwidth and therefore an increased effective electromagnetic coupling coefficient κ².

### SUMMARY

In one aspect of the disclosure, A BAW resonator is provided. The BAW resonator includes a piezoelectric material, a first electrode coupled to the piezoelectric material, and a second electrode coupled to the piezoelectric material. The piezoelectric material is arranged between the first electrode and the second electrode. The piezoelectric material is LiNbO₃ and has an orientation with Euler angles selected from [0°±5°; 130°±15°; n°±5°], or a symmetrical equivalent, where n is variable (the third value n may also be instead represented by a variable Ψ that may be variable while still achieving a desired acoustic wave mode for the BAW resonator).

In another aspect of the disclosure, a BAW resonator is provided. The BAW resonator includes a piezoelectric material, a first electrode coupled to the piezoelectric material, and a second electrode coupled to the piezoelectric material. The piezoelectric material is arranged between the first electrode and the second electrode. The piezoelectric material is LiTaO₃ and has an orientation with Euler angles selected from [0°±5°; 130°±15°; n°±5°], or a symmetrical equivalent, where n is variable.

In yet another aspect of the disclosure, a BAW resonator is provided. The BAW resonator includes a piezoelectric material, a first electrode coupled to the piezoelectric material, and a second electrode coupled to the piezoelectric material. The piezoelectric material is arranged between the first electrode and the second electrode. The piezoelectric material is LiNbO₃ and has an orientation with Euler angles selected from at least one of the following: [0°±5°; 130°±15°; n°±5°] where n is variable; or [0°±5°; 130+n*180°±15°; n°±5°]; or [Φ+n*120°±5°, 130°±15, n°±5°]; or [Φ+n*60°, (−1)\hat{ }n*130°±15, n°±5°].

In yet another aspect of the disclosure, a BAW resonator is provided. The BAW resonator includes a piezoelectric material, a first electrode coupled to the piezoelectric material, and a second electrode coupled to the piezoelectric material. The piezoelectric material is arranged between the first electrode and the second electrode. The piezoelectric material is LiTaO₃ and has an orientation with Euler angles selected from at least one of the following: [0°±5°; 130°±15°; n°±5°] where n is variable; or [0°±5°; 130+n*180°±15°; n°±5°]; or [Φ+n*120°±5°, 130°±15, n°±5°]; or [Φ+n*60°, (−1)\hat{ }n*130°±15, n°±5°].

### BRIEF DESCRIPTION OF THE DRAWINGS

FIG. 1 shows elements of an active structure of an electroacoustic resonator.

FIG. 2A shows an example of a BAW resonator according to one or more aspects of the disclosure.

FIG. 2B shows another example of a BAW resonator according to one or more aspects of the disclosure.

FIG. 2C shows another example of a BAW resonator of the FBAR-type according to one or more aspects of the disclosure.

FIGS. 3 and 4 illustrate frequency-dependent BAW-device impedance traces for different Euler angles Θ of lithium niobate (FIG. 3) and lithium tantalate (FIG. 4).

FIG. 5 illustrates a BAW-device impedance comparison between a BAW resonator comprising lithium niobate as a monocrystalline piezoelectric material, lithium tantalate as a monocrystalline piezoelectric material, and of a BAW resonator including polycrystalline aluminium nitride with 7% scandium doping.

FIG. 6 illustrates the coupling coefficient (left portion) of a longitudinal wave mode and of an unwanted shear-mode (right portion) for different Euler angles Θ and Φ for lithium niobate (top portion) and lithium tantalate (bottom portion).

FIG. 7 is a schematic diagram of an electroacoustic filter circuit that may include BAW resonators as described herein.

FIG. 8 is a functional block diagram of at least a portion of an example of a simplified wireless transceiver circuit in which the filter circuit of FIG. 7 may be employed.

FIG. 9 is a diagram of an environment that includes an electronic device that includes a wireless transceiver such as the transceiver circuit of FIG. 8.

### DETAILED DESCRIPTION

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

New frequency bands for future communication systems such as hardware for the fifth generation (new radio) (5G NR) creates a demand for filters with an increased fractional bandwidth and therefore an increased effective electromagnetic coupling coefficient κ².

One type of piezoelectric material for BAW resonators is aluminium nitride. The coupling coefficient of aluminium nitride can be increased by doping the aluminium nitride, e.g. with scandium. With respect to scandium-doped aluminium nitride, increasing the doping level in some cases may increase acoustic losses, resulting in higher insertion losses of corresponding RF-filters. Further, with respect to the need for increased working frequencies, if electrode dimensions are scaled down to achieve a similar coupling coefficient, the effective sheet resistance of the devices is increased. As a result, new higher frequency BAW stacks may need thicker electrodes, resulting in a reduced coupling coefficient and a reduction of the quality factor because acoustic energy is redistributed in the overall layer stack with less being present in the typically higher-acoustic-quality piezoelectric material.

Thus, a BAW resonator is desired that is compatible with the needs of future mobile communication standards, has an increased quality factor and provides: an increased fractional bandwidth, an increased effective coupling coefficient, high working frequencies, and low losses. Further, spurious modes should be reduced or eliminated to facilitate the use in carrier aggregation systems. Furthermore, a reduced spatial size and an easy-to-implement manufacturing method are also desirable.

A BAW resonator includes a piezoelectric material, a first electrode coupled to the piezoelectric material and a second electrode coupled to the piezoelectric material. The piezoelectric material is arranged between the first and the second electrode. Further, in certain aspects of the disclosure, in contrast to a piezoelectric material realized through a layer deposition process (e.g., sputtering), the piezoelectric material of the BAW resonator is one that is derived from a wafer or boule (e.g., in the form of a bulk wafer) and that in certain aspects may be substantially monocrystalline.

In particular, certain BAW resonators use an aluminum nitride based piezoelectric material provided by a layer deposition technique such as sputtering.

In accordance with certain aspects herein, BAW resonators are provided that include a piezoelectric material that may be provided with an optimum orientation of the piezoelectric axis with respect to the extension of the electrodes. In an aspect, the piezoelectric material is derived from a boule that is cut into wafers and has a surface normal that corresponds to the rotated Z-axis specified by the Euler Angles disclosed herein. In the BAW Resonator configuration, the wafer normal direction is aligned with the top and bottom electrode surface normal in order to predominantly excite the high coupling, low spurious longitudinal mode of interest. The piezoelectric materials formed in a way to have such a particular axis (e.g., such as certain monocrystalline piezoelectric materials) may allow for obtaining an improved electroacoustic coupling coefficient while maintaining a high quality factor even at high frequencies. Thus, an improved BAW resonator is obtained that allows substantially improved RF-filters having increased fractional bandwidth at high frequencies.

In accordance with certain aspects of the disclosure, the piezoelectric material for the BAW resonators is selected from quartz, lithium niobate (LiNbO₃) and lithium tantalate (LiTaO₃).

Further, in accordance with certain aspects of the disclosure, the piezoelectric material is lithium niobate and has an orientation with the Euler angles selected from [0°±5°; 35°±15°; n°±5°] and [0°±5°; 130°±15°; n°±5°] where the ‘n’ denotes a variable angle for the last angle. The last angle (that may be indicated as Ψ as described further below) may vary while nonetheless achieving the acoustic wave mode desired and therefore may have a variety of values while still providing the desired longitudinal mode described herein. However, in some aspects the last angle may be 0°±5° as an example.

In certain other aspects of the disclosure, the piezoelectric material is lithium tantalate and has an orientation with the Euler angles selected from [0°±5°; 0° . . . 30°; n°±5°] and [0°±5°; 130°±15°; n°±5°] where n denotes a variable angle as noted above but may be 0°±5° in some aspects.

The Euler angles (Φ, Θ, Ψ) may be indicated in accordance with one example as follows. Firstly, a set of axes x, y, z are taken as a basis, which are the crystallographic axes of the piezoelectric material. The first angle Φ specifies by what magnitude the x axis and the y axis are rotated about the z axis, the x axis being rotated in the direction of the y axis. A new set of axes x′, y′, z′ correspondingly arises where z=z′. In a further rotation, the z′ axis and the y′ axis are rotated about the x′ axis by the angle Θ. In this case, the x′ axis is rotated in the direction of the z′ axis. A new set of axes x″, y″, z″ correspondingly arises where x′=x″. In a third rotation, the x″ axis and the y″ axis are rotated about the z″ axis by the angle Ψ. In this case, the x″ axis is rotated in the direction of the y″ axis. A third set of axes x′″, y′″, z′″ thus arises z″=z′″. In this case, the y′″ axis and the x′″ axis are parallel to the surface of the piezoelectric material. The z′″ axis is the normal to the surface of the piezoelectric material. The z′″ axis specifies the direction of propagation of the acoustic waves.

A BAW resonator generally works with a longitudinal wave mode establishing a standing wave propagating in a vertical direction between the electrodes of the electrode stack comprising the piezoelectric material sandwiched between the electrodes. Note that in some cases a BAW resonator design may also be possible where a shear mode is predominately excited with a proper choice of orientation.

It is possible that the BAW resonator as disclosed herein is an FBAR-type resonator including a cavity or an SMR-type resonator including an acoustic mirror.

An FBAR-type resonator (FBAR=film bulk acoustic resonator) acoustically decouples the electroacoustically active element including the electrodes and the piezoelectric material by means of a cavity below the bottom electrode. Thus, a large step of the acoustic impedance at the interface between the bottom electrode and the cavity (which could be filled with a gas or which could be empty) is provided. Thus, the acoustic wave is reflected at the interface and acoustic energy is confined to the active area. Correspondingly, an efficient energy confinement and a high quality factor can be obtained.

In an SMR-type resonator (SMR=solidly mounted resonator) acoustic energy is confined by arranging the active element of the resonator on an acoustic mirror comprising layers of high and low acoustic impedances. At each interface between a material of a high acoustic impedance and of a low acoustic impedance a significant portion of the acoustic wave is reflected. The thicknesses of the mirror layers are such that a Bragg mirror structure is obtained such that the active area of the resonator is acoustically decoupled from its environment.

The BAW resonator has a resonance frequency and an anti-resonance frequency. The resonance frequency or the anti-resonance frequency can be above 3 GHz in certain aspects.

The working frequency range of the BAW resonator, which may be indicated by the resonance frequency and by the anti-resonance frequency of the resonator, depends on the thickness (in the vertical direction) of the piezoelectric material. Specifically, the operation frequency is reciprocal to the thickness. Thus, higher working frequencies correspond to smaller thicknesses. Further, the demands concerning the precision of the thickness are even stricter with higher frequencies.

The thin monocrystalline piezoelectric materials in accordance with aspects of the disclosure have particular piezoelectric orientations and have a high surface quality at the bottom side and at the top side of the piezoelectric material such that an acoustically well-defined interface to neighboring layers of the corresponding layer stack of the resonator can be obtained. In this way, a resonator with high electric and acoustic performance can be obtained.

In certain aspects, the Euler angles described herein provide a longitudinal acoustic wave mode and exhibit good electroacoustic coupling coefficients for the wanted acoustic main modes and substantially no acoustic response from unwanted spurious modes such as unwanted shear modes at neighboring frequencies.

While spurious modes at frequencies that are sufficiently far away from the working frequency of the resonator may not be regarded as that severe in other resonators, where carrier aggregation is concerned, then even unwanted resonances at frequencies far away from the working frequency may be problematic because in carrier aggregation systems several frequencies may be simultaneously used by further resonators in further filters. Thus, it is desirable that spurious modes should be reduced or eliminated even at remote frequencies.

The monocrystalline piezoelectric material can be obtained via a process that ensures the integrity of the bottom and top surface of the piezoelectric material establishing the interface towards the resonator's electrodes.

Possible exemplary materials for the electrodes are tungsten, molybdenum, aluminum, copper, aluminum copper alloys, or a multilayer system comprises two or more layers including these materials, and the like.

A possible exemplary material for a carrier substrate is silicon or doped silicon that can be provided with a high purity.

A possible exemplary material for layers of low acoustic impedance is a silicon oxide, e.g. silicon dioxide.

A possible exemplary material for layers of high acoustic impedance is tungsten, platinum, iridium, gold or copper.

A dielectric, e.g. silicon nitride (SiN), can be as a passivation and/or a trim layer. It can also be used as an etch-stop and/or passivation layer, e.g. under the bottom electrode. Further, aluminum nitride (AlN) can be used as alternative to SiN. A conducting material, e.g. titanium nitride (TiN), can be used as an etch-stop layer for structuring the bottom electrode for technologies that have optional W detuning just below the piezoelectric material. Also, TiN can be used also as an etch-stop layer.

A possible exemplary material for an adhesion layer between functional layers of the layer stack can be titanium.

A possible exemplary material for any sacrificial layer is molybdenum that can temporarily be deposited at a specific position where later a cavity for confining acoustic energy to the active area should be located. In an etching step an etching agent can be xenon difluoride (XeF2).

Further, it should be noted that, due to possible symmetries of crystal structure of the piezoelectric material, equivalent Euler angles are also possible. Thus, when the piezoelectric material has a threefold symmetry axis around the z axis then integer multiples of 120° for the first Euler angle Φ are equivalent. Similarly, for a positive second Euler angle Θ the corresponding negative Euler angle Θ is also possible due to a mirror plane in lithium tantalate or lithium niobate.

Correspondingly, an integer multiple of 180° can be added to the second Euler angle θ resulting in an equivalent orientation.

An RF-filter may include one or more BAW resonators implemented with the piezoelectric materials and Euler angles as defined and described above and below.

The RF-filter may have a ladder-type like circuit topology or lattice-type like circuit topology.

In a ladder-type like circuit topology a plurality of one, two, or more series resonators are electrically connected in series in a signal path. Shunt paths comprising parallel resonators can electrically connect the signal path to ground (or some reference potential).

In a lattice-type like circuit topology an input port has a first connection and a second connection and an output port has a first connection and a second connection. Further, one resonator or signal line electrically connects the first connection of the first port to the second connection of the second port, establishing a cross-connection.

Further, the RF-filter can be a reception filter of a mobile communication device or a transmission filter of a mobile communication device. Specifically, it is possible to use such filters as one or more reception filters and as one or more transmission filters in a corresponding duplexer. The duplexer can further comprise an impedance matching circuit at a common port electrically connected between the transmission filter and the reception filter.

Further, it is possible that a method of manufacturing the BAW resonator as described above comprises one or more operations including:
providing a cavity and/or an acoustic mirror,
providing one or more adhesion layers,
providing one or more trimming layers and/or passivation layers,
providing one or more wafer bond layers,
providing one or more sacrificial layers,
removing a sacrificial material from a sacrificial layer.

Thus, with a plurality of intermediate steps concerning the arrangement of an additional single layer or of a plurality of additional layers allows stacking layers such that well-defined acoustic impedances are obtained of the overall layer stack such that the overall resonator provides excellent acoustic and electric properties. The total number of layers of the resonator can be 5, 10, 15, 20 and more. The method includes providing the piezoelectric material (with materials and Euler angles as described herein) along with providing bottom and top electrodes).

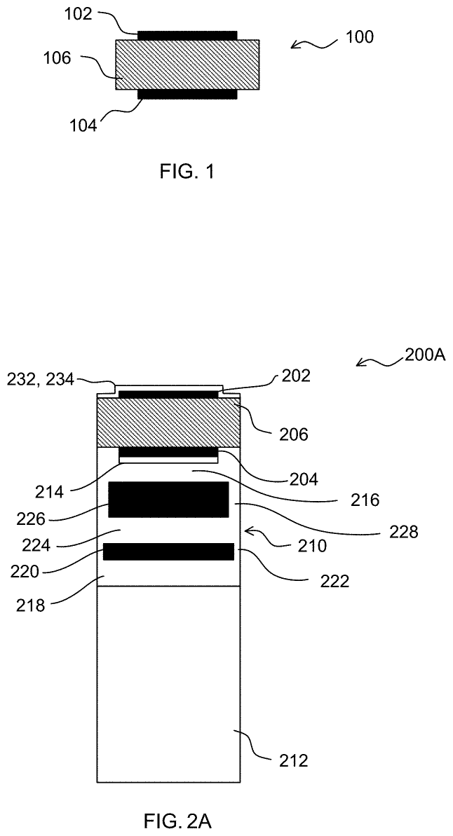

FIG. 1 shows a unit of an electroacoustic resonator 100. The unit establishes an active area or at least a significant portion of the active area of the resonator 100 and includes a first electrode 102, a second electrode 104, and a piezoelectric material 106 realized as a piezoelectric crystal. The first electrode 102 and the second electrode 104 establish the top and the bottom electrode, respectively, depending on the orientation of the resonator. The piezoelectric material 106 is sandwiched between the first electrode 102 and the second electrode 104. The vertical direction between the electrodes corresponds to the z″ direction defined by the Euler angles where a longitudinal wave mode propagates. The x″ and y″ directions are within the plane of the top and bottom electrodes. Due to reflections a standing wave is obtained. The resonance, and the anti-resonance frequency being higher than the resonance frequency, are substantially defined by the thickness in the vertical direction of the piezoelectric material 106 and the electro acoustic coupling coefficient κ², respectively and thickness and material of the electrodes 102, 104.

The provision of the monocrystalline material as the piezoelectric material 106, with Euler angles as described herein, sandwiched between the two electrodes allows an increased fractional bandwidth even at high frequencies as, for example, desired for the new 5G frequency bands, by providing an increased effective electroacoustic coupling coefficient κ² such that a high quality factor and low losses together with low or reduced spurious modes such as shear-modes are obtained such that the resonator is well-suited for duplexers or multiplexers working in carrier aggregation (CA) modes.

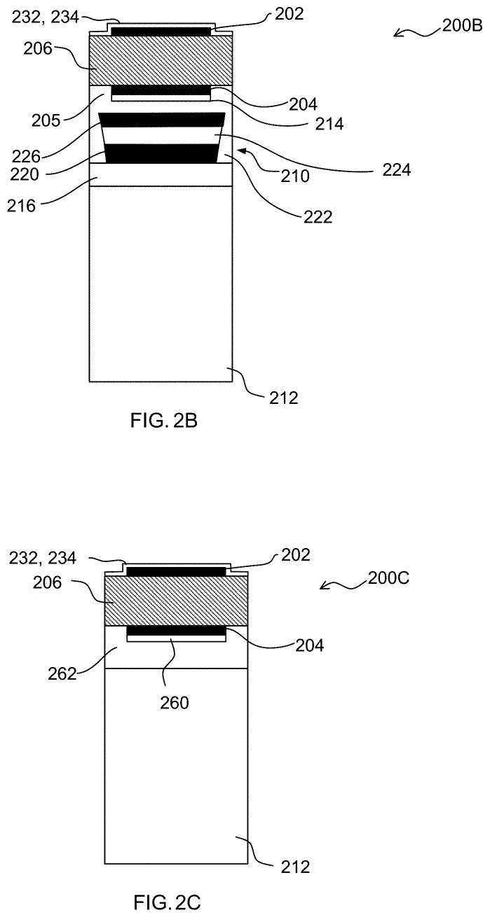

FIG. 2A illustrates a possible BAW resonator 200A being a SMR-type resonator comprising an acoustic mirror 210 below the bottom electrode 204 to confine acoustic energy in the active area and to prevent energy dissipation into the carrier substrate 212. The top electrode 202 of the resonator 200 is covered with a passivation layer 232 and/or a trimming layer 234. The bottom electrode 204 has a two-layer construction.

Similarly, FIG. 2B illustrates a BAW resonator 200B of the SMR-type where the acoustic mirror 210 prevents or significantly reduces energy dissipation.

FIG. 2C illustrates a BAW resonator 200C of the FBAR-type where a cavity 260 below the bottom electrode 204 acoustically isolates the active structure from the carrier substrate.

The BAW resonator according to FIG. 2A includes a piezoelectric material 206, particularly a piezoelectric material 206 from a piezoelectric crystal (PC) derived from a wafer or boule and that in certain aspects may be substantially monocrystalline.

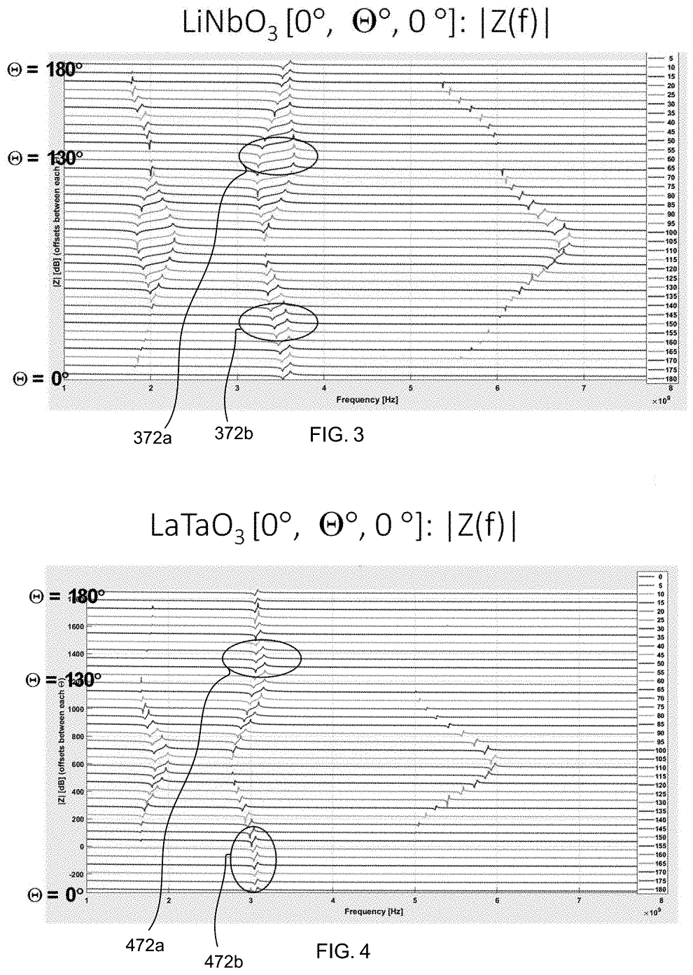

In one aspect, the piezoelectric material 206 is LiNbO₃ and has an orientation with the Euler angles selected from [0°±5°; 130°±15°; n°±5°] where n indicates a variable value but in certain aspects may be 0°±5° (e.g., could also be represented as [0°±5°; 130°±15°; Ψ]. As described above, an integer multiple of 180° can be added to the second Euler angle Θ resulting in an equivalent orientation (e.g., flipped wafer) such that the piezoelectric material 206 may have an orientation with the Euler angles selected from [0°±5°; 310°±15°; n°±5°] (or more generally [0°±5°; 130+n*180°±15°; n°±5°]). It should further be appreciated that based on a 3-fold symmetry around Z, there may be other corresponding Euler angles that may have the same or similar properties as those described herein. For example, a piezoelectric material 206 with an Euler angle defined by [Φ, Θ, Ψ] as noted above may have similar properties to a piezoelectric material 206 with an Euler angle defined by [Φ+n*120°, Θ, Ψ]. Therefore in this particular case, the LiNbO₃ based piezoelectric material 206 may further have an Euler angle selected from [Φ+n*120°, 130°±15, n°±5°] (e.g., for example, [120°±5°, 130°±15; and n°±5°] and the like). Furthermore, a piezoelectric material 206 with an Euler angle defined by [Φ, Θ, Ψ] as noted above, for Φ→Φ+60° then X′→−X′, so [Φ, Θ, Ψ] may be generally equivalent to a piezoelectric material having an Euler angle selected from [Φ+n*60°, (−1)\hat{ }n*Θ, Ψ]. As such, in this particular case, the LiNbO₃ based piezoelectric material 206 may have an orientation with the Euler angles selected from [Φ+n*60°, (−1)\hat{ }n*130°±15, n°±5°] (e.g., for example, [60°±5°, −130°±15; n°±5°] and the like). Note that the flipped wafer scenario (adding 180° to Θ) may be additionally applied to these 3-fold symmetry cases as well. For example, the Euler angles may be [60°±5°, −130°±15; n°±5°] as well as [60°±5°, −130°+180°=50°±15; n°±5°] and the like. In some aspects, as is illustrated as having reduced shear modes with respect to FIG. 3, the piezoelectric material 206 is LiNbO₃ and has an orientation with the Euler angles selected from [0°±5°; 130°±3°; n°±5°].

In another aspect, the piezoelectric material 206 is LiTaO₃ and has an orientation with the Euler angles selected from [0°±5°; 130°±15°; n°±5°] where n indicates a variable value but in certain aspects may be 0°±5°. As described above, an integer multiple of 180° can be added to the second Euler angle θ resulting in an equivalent orientation such that an Euler angle is selected from [0°±5°; 310°±15°; 0°±5°]. Likewise the 3-fold symmetry properties describe in the preceding paragraph may apply as well when the piezoelectric material 206 is LiTaO₃ and therefore such a piezoelectric material 206 may have an Euler angle selected from angles as described in the preceding paragraph. In some aspects, as is illustrated as having reduced shear modes with respect to FIG. 4, the piezoelectric material 206 is LiTaO₃ and has an orientation with the Euler angles selected from [0°±5°; 130°±3°; n°±5°].

A bottom electrode 204 is provided that may include a multi-layer construction (layers not illustrated) having a stack of different conductive materials that may include, but is not limited to a material with a high acoustic impedance, e.g. tungsten, directly arranged at the interface of the piezoelectric material 206, an aluminum copper alloy, and other layers to improve the effective electrical conductivity of the electrode. Various multi-layer configurations for the bottom electrode 204 (or top electrode 202) are contemplated.

An additional low acoustic impedance material 214 may be provided that can be a material of a low acoustic impedance such as SiO2. Silicon dioxide can also be used as a dielectric material in an electrically insulating layer.

A later bonding layer 216 may also be provided. The material of the bonding layer 216 can also be a material of a low acoustic impedance.

A carrier substrate 212 is further included. An isolation layer 218 is included, which may be a material of a low acoustic impedance e.g., SiO2, and is arranged on the carrier substrate 212. The carrier substrate 212 can include or consist of silicon. The isolation layer 218 can include an electrically insulating material such as silicon dioxide or consist of silicon dioxide.

A material of a high acoustic impedance 220 is arranged on the isolation layer 218 (where the isolation layer 218 may be a material of low acoustic impedance).

The material of high acoustic impedance 220 can be embedded in the material of low acoustic impedance as denoted by the low acoustic impedance portion 222 on the side of the high acoustic impedance material 220.

Another material of low acoustic impedance 224 is arranged on the material of high acoustic impedance 220. The material of low acoustic impedance 224 can be of the same material as the material next to or below the material of high acoustic impedance (e.g., 218 and/or 222) but other low acoustic impedance materials are possible.

Another material of high acoustic impedance 226 is arranged on the material of the low acoustic impedance 224.

The material of high acoustic impedance 226 can be embedded in the material of low acoustic impedance as denoted by the low acoustic impedance portion 228 on the side of the high acoustic impedance material 226.

Material for the bonding layer 216 is arranged on the material of high acoustic impedance 226.

The materials of the corresponding opposing bonding layers can be bonded together to establish a monolithic unit. While certain bonding layers are described, it should be appreciated that there may be other regions used for the bonding regions throughout the stack.

The piezoelectric material 206 is provided at the desired thickness (e.g., based on the desired operating frequency). The material of the top electrode 202 is arranged on the piezoelectric material 206.

The top side of the piezoelectric material 206 and the top side and the side surfaces of the top electrode 202 may be covered with a layer that can be a trimming layer 234 and/or a passivation layer 232.

Further packaging structures and interconnects (not shown) may be further added around the resonator of FIG. 2A.

In FIG. 2B, the BAW resonator 200B includes a piezoelectric material 206 with a configuration that is similar as described with respect to FIG. 2A (e.g., derived from a wafer or boule and that in certain aspects may be substantially monocrystalline and having Euler angles as described above with reference to FIG. 2A with an orientation that provides for a longitudinal acoustic wave mode).

The BAW resonator 200B of FIG. 2B includes a bottom electrode 204 similar to that described with reference to FIG. 2A having a two-layered electrode and arranged on the piezoelectric material 206 (or at least arranged to provide a high level of electroacoustic coupling). An additional material 214 (having a lower acoustic impedance) may be provided such as SiO2. Silicon dioxide can also be used as a dielectric material in an electrically insulating layer.

The bottom electrode 204 is embedded in a material of low acoustic impedance 205. Materials of alternating acoustic impedance 220, 224, and 226 are included that form the acoustic mirror 210. The acoustic mirror 210 is embedded in a material of a low acoustic impedance 222 (the material 222 may be the same as 214). In some aspects, the bottom electrode 204 and acoustic mirror 210 may be constructed on the wafer including the piezoelectric material and then together attached to the carrier substrate 212.

The BAW resonator 200B of FIG. 2B includes a carrier substrate 212. A bonding layer 216 is arranged on the carrier substrate 212 that may be provided to bond with a stack including the layers of the acoustic mirror 210.

The BAW resonator 200B of FIG. 2B includes a top electrode 202 arranged on the piezoelectric material 206.

An additional passivation layer 232 and/or a trimming layer 234 may be arranged on the free top and side surfaces of the piezoelectric material 206 and of the top electrode 202.

Then when bonded or formed together, a monolithic unit is established. As noted above, the points at which bonds are determined may be different for different processes. As such bonding layers as described herein may be provided at different points in the stack than that described.

The piezoelectric material 206 is provided at the desired thickness (e.g., based on the desired operating frequency) such as having a thickness to result in a operating frequency above 3 GHz.

Further packaging structures and interconnects (not shown) may be further added around the resonator 200B of FIG. 2B.

The BAW resonator 200C of FIG. 2C is of the FBAR-type. The BAW resonator 200C of FIG. 2C includes a piezoelectric material 206 with a configuration that is similar as described with respect to FIG. 2A (e.g., derived from a wafer or boule and that in certain aspects may be substantially monocrystalline and having Euler angles as described above with reference to FIG. 2A with an orientation that provides for a longitudinal acoustic wave mode). A bottom electrode 204 is arranged on one side of the piezoelectric material 206.

In some aspects, during a process for forming the BAW resonator 200C, a sacrificial layer may be provided on the bottom electrode 204 that is later removed to form the cavity 260.

As such, a cavity 260 is provided on the side of the bottom electrode 204 opposite of the piezoelectric material 206. The bottom electrode 204 and the cavity 260 are embedded in a material of low acoustic impedance 262 which extends further below the cavity (and can be a bonding layer) to interface with a carrier substrate 212.

The BAW resonator 200C of FIG. 2C includes a carrier substrate 212. In some aspects, a bonding layer may be arranged on the carrier substrate 212 to interface with a bonding layer provided below the cavity 260. When bonded, the resulting monolithic structure will result in a material of low acoustic impedance 262 between the carrier substrate 212 and the cavity 260.

The piezoelectric material 206 is provided with a desired thickness. The top electrode 202 is arranged on the piezoelectric material 206. A passivation layer 232 and/or trimming layer 234 may be arranged on the free top and side surfaces of the piezoelectric material 206 and the top electrode 202.

FIGS. 3 and 4 illustrate frequency-dependent BAW-device impedance traces for different Euler angles Θ of lithium niobate (FIG. 3) and lithium tantalate (FIG. 4).

The ellipsis 372a and 372b illustrated in FIG. 3 indicate electroacoustic resonances and anti-resonances (specifically the absolute value of the impedance of the corresponding resonator) of a BAW resonator as described above with lithium niobate being the monocrystalline piezoelectric material at frequencies around 3.5 GHz for 0 around 15° and 130° for the main, longitudinal wave mode. The area indicated by the ellipsis 372a and 372b indicates a particular orientation with a main longitudinal wave mode in addition to where there are reduced or substantially zero unwanted, spurious shear modes at lower and higher frequencies. As such, a piezoelectric material with an orientation as highlighted by the ellipsis 372a and 372b (e.g., [0°±5°; 130°±15°; 0°±5°]) may provide a particular orientation that provides high coupling while reducing spurious shear modes and providing a main longitudinal acoustic wave mode. In particular, as illustrated, a piezoelectric material with an orientation [0°±5°; 130°±3°; 0°±5°] may provide the high coupling while substantially reducing shear modes.

The ellipsis 472a and 472b illustrated in FIG. 4 indicate electroacoustic resonances and anti-resonances (specifically the absolute value of the impedance of the corresponding resonator) of a BAW resonator as described above for lithium tantalate where a wanted acoustic longitudinal main mode with a good electroacoustic coupling coefficient and without spurious modes at lower or higher frequencies are present. The area indicated by the ellipsis 472a and 472b indicates a particular orientation with a main longitudinal wave mode in addition to where there are reduced or substantially zero unwanted, spurious shear modes at lower and higher frequencies. As such, by providing a piezoelectric material with an orientation as highlighted by the ellipsis 472a and 472b (e.g., [0°±5°; 130°±15°; n°±5°]) may provide a particular orientation that provides high coupling while reducing spurious shear modes and providing a main longitudinal acoustic wave mode.

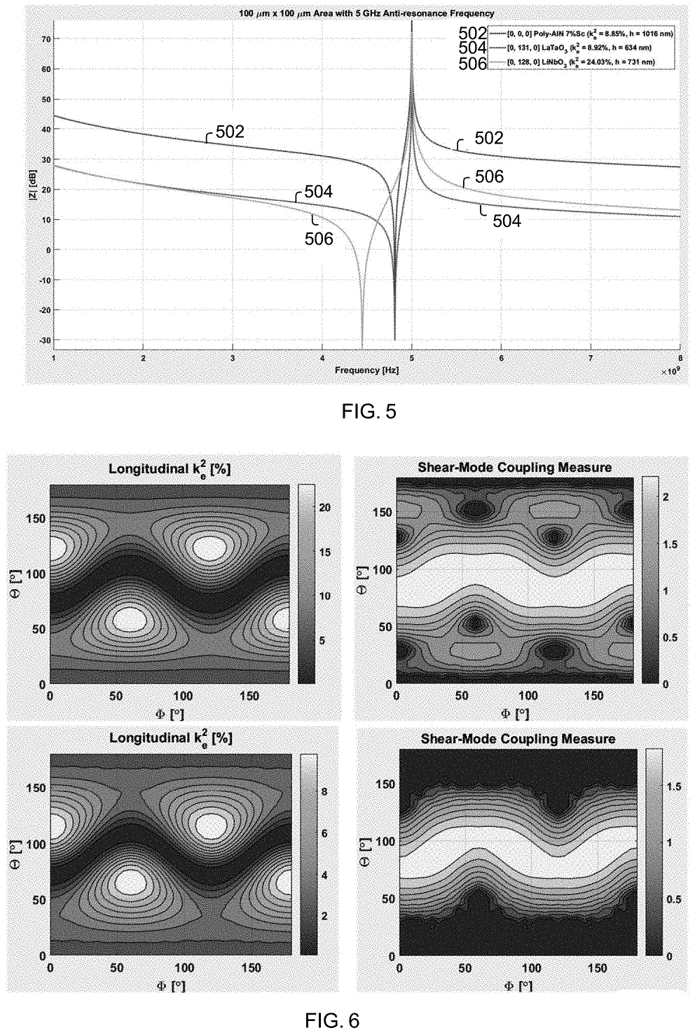

FIG. 5 shows a comparison of absolute values of impedances of example electro acoustic resonators with different materials for the piezoelectric layer. Curve 502 shows the frequency response of an example of a BAW resonator where the piezoelectric material is polycrystalline aluminum nitride with a 7% scandium doping. The thickness of the piezoelectric material is 1060 nm. The electroacoustic coupling coefficient κ2 is 8.85%. Further, curve 504 illustrates the resonance behavior of an example of a BAW resonator having monocrystalline lithium tantalate as the piezoelectric material. The thickness of the lithium tantalate in the vertical direction is 634 nm. The coupling coefficient is 8.92%. The lithium tantalate has the Euler angle [0°, 131°, 0°]. Further, curve 506 illustrates the resonance behavior of an example of a BAW resonator with lithium niobate being the monocrystalline piezoelectric material. The lithium niobate has a thickness in the vertical direction of 731 nm. The coupling coefficient of the resonator κ2 is 24.03%. The lithium niobate has an orientation with the Euler angle [0°, 128°, 0°].

The thicknesses of the piezoelectric materials are chosen such that the anti-resonance frequencies of the resonators coincide at 5 GHz. The resonators' area is 100 μm×100 μm.

It is clearly recognizable that the example resonators having the monocrystalline piezoelectric material provide improved electroacoustic performance in certain aspects. Specifically, the coupling coefficient determining the pole zero distance of the resonator of lithium niobate is significantly improved.

FIG. 6 shows the longitudinal coupling coefficient κ2 (left two plots) and a measure of shear-mode content in the |Z| plots (right two plots) for lithium niobate (top two plots) and for lithium tantalate (bottom two plots) for different Euler angles Φ and Θ with a third Euler angle Ψ being zero in corresponding contour blots. These blots together with the blots shown in FIGS. 3 and 4 illustrate promising Euler angles for the monocrystalline piezoelectric materials of the BAW resonators with high coupling factors and reduced shear modes such that substantially improved resonators and filters can be obtained.

The resonators, filters and manufacturing methods are not limited to the details described above and shown in the figures. Specifically, the resonators can comprise further elements and structures for electrically contacting the electrodes, for further improving the wave modes and for acoustically decoupling the resonator stacks from one another when a plurality of resonator stacks are arranged on a common carrier substrate to establish an RF-filter. Correspondingly, RF-filters can comprise further circuit components and sub-circuits, e.g. impedance matching circuits and means for hermetically sealing sensitive layer structures from environmental influences.

In an aspect, a method for providing a BAW resonator 200A may be provided. The method is described with respect to the BAW resonator 200A of FIG. 2A as an example but may also be applied with respect to the BAW resonators 200B and 200C described with respect to FIGS. 2B and 2C or otherwise as described in the disclosure. The method may include providing a piezoelectric material 206, a first electrode 202 coupled to the piezoelectric material, and a second electrode 204 coupled to the piezoelectric material 206. The piezoelectric material 206 is arranged between the first electrode 202 and the second electrode 204. Providing the piezoelectric material 206 may include providing a piezoelectric material 206 formed from LiTaO₃ and having an orientation with Euler angles selected from at least one of the following: [0°±5°; 130°±15°; n°±5°] where n is variable; or [0°±5°; 130+n*180°±15°; n°±5°]; or [Φ+n*120°±5°, 130°±15, n°±5°]; or [Φ+n*60°, (−1)\hat{ }n*130°±15, n°±5°].

In another aspect, providing the piezoelectric material 206 may include providing a piezoelectric material 206 formed from LiNbO₃ and having an orientation with Euler angles selected from at least one of the following: [0°±5°; 130°±3°; n°±5°], where n is variable; or [0°±5°; 130+n*180°±3°; n°±5°]; or [Φ+n*120°±5°, 130°±3, n°±5°]; or [Φ+n*60°, (−1)\hat{ }n*130°±3, n°±5°].

The BAW resonators described above may be used in a variety of applications.

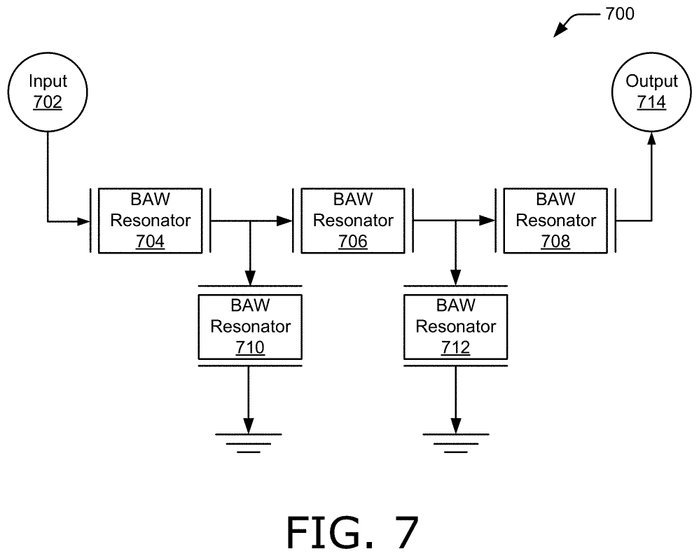

FIG. 7 is a schematic diagram of an electroacoustic filter circuit 700 (e.g., RF filter circuit) that may include the BAW resonators described above. The filter circuit 700 provides one example of where the resonators described above may be used. The filter circuit 700 includes an input terminal 702 and an output terminal 714. Between the input terminal 702 and the output terminal 714 a ladder network of BAW resonators is provided. The filter circuit 700 includes a first BAW resonator 704, a second BAW resonator 706, and a third BAW resonator 708 all electrically connected in series between the input terminal 702 and the output terminal 714. A fourth BAW resonator 710 (e.g., shunt resonator) has a first terminal connected between the first BAW resonator 704 and the second BAW resonator 706 and a second terminal connected to a ground potential. A fifth BAW resonator 712 (e.g., shunt resonator) has a first terminal connected between the second BAW resonator 706 and the third BAW resonator 708 and a second terminal connected to a ground potential. The electroacoustic filter circuit 700 may, for example, be a bandpass circuit having a passband with a selected frequency range. The illustrated ladder network provides just one example of a filter schematic and other filter arrangement or applications for BAW resonators are contemplated.

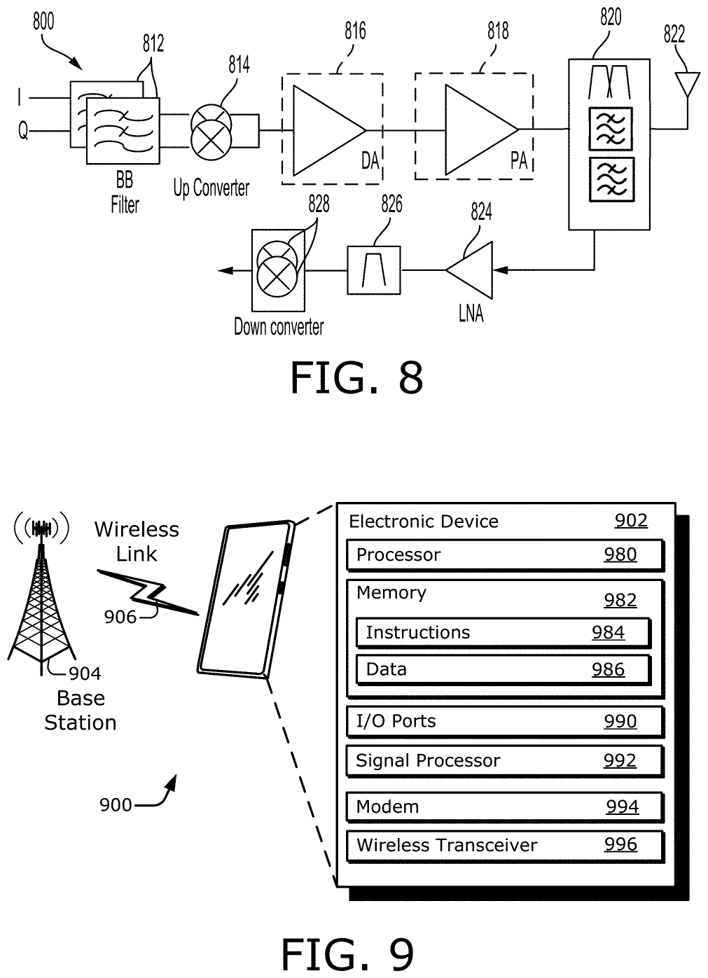

FIG. 8 is a functional block diagram of at least a portion of an example of a simplified wireless transceiver circuit 800 in which the filter circuit 700 of FIG. 7 may be employed. The transceiver circuit 800 is configured to receive signals/information for transmission (shown as I and Q values) which is provided to one or more base band filters 812. The filtered output is provided to one or more mixers 814. The output from the one or more mixers 814 is provided to a driver amplifier 816 whose output is provided to a power amplifier 818 to produce an amplified signal for transmission. The amplified signal is output to the antenna 822 through one or more filters 820 (e.g., duplexers if used as a frequency division duplex transceiver or other filters). The one or more filters 820 may include the filter circuit 700 of FIG. 7. The antenna 822 may be used for both wirelessly transmitting and receiving data. The transceiver circuit 800 includes a receive path through the one or more filters 820 to be provided to a low noise amplifier (LNA) 824 and a further filter 826 and then down-converted from the receive frequency to a baseband frequency through one or more mixer circuits 828 before the signal is further processed (e.g., provided to an analog digital converter and then demodulated or otherwise processed in the digital domain). There may be separate filters for the receive circuit (e.g., may have a separate antenna or have separate receive filters) that may be implemented using the filter circuit 700 of FIG. 7.

FIG. 9 is a diagram of an environment 900 that includes an electronic device 902 that includes a wireless transceiver 996 such as the transceiver circuit 800 of FIG. 8 (and that may incorporate filters that use the BAW resonators described above). In the environment 900, the electronic device 902 communicates with a base station 904 through a wireless link 906. As shown, the electronic device 902 is depicted as a smart phone. However, the electronic device 902 may be implemented as any suitable computing or other electronic device, such as a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, and so forth.

The base station 904 communicates with the electronic device 902 via the wireless link 906, which may be implemented as any suitable type of wireless link. Although depicted as a base station tower of a cellular radio network, the base station 904 may represent or be implemented as another device, such as a satellite, terrestrial broadcast tower, access point, peer to peer device, mesh network node, fiber optic line, another electronic device generally as described above, and so forth. Hence, the electronic device 902 may communicate with the base station 904 or another device via a wired connection, a wireless connection, or a combination thereof. The wireless link 906 can include a downlink of data or control information communicated from the base station 904 to the electronic device 902 and an uplink of other data or control information communicated from the electronic device 902 to the base station 904. The wireless link 906 may be implemented using any suitable communication protocol or standard, such as 3rd Generation Partnership Project Long-Term Evolution (3GPP LTE, 3GPP NR 5G), IEEE 802.11, IEEE 802.16, Bluetooth™, and so forth.

The electronic device 902 includes a processor 980 and a memory 982. The memory 982 may be or form a portion of a computer readable storage medium. The processor 980 may include any type of processor, such as an application processor or a multi-core processor, that is configured to execute processor-executable instructions (e.g., code) stored by the memory 982. The memory 982 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the memory 982 is implemented to store instructions 984, data 986, and other information of the electronic device 902, and thus when configured as or part of a computer readable storage medium, the memory 982 does not include transitory propagating signals or carrier waves.

The electronic device 902 may also include input/output ports 990 (I/O ports 116). The I/O ports 990 enable data exchanges or interaction with other devices, networks, or users or between components of the device.

The electronic device 902 may further include a signal processor (SP) 992 (e.g., such as a digital signal processor (DSP)). The signal processor 992 may function similar to the processor and may be capable executing instructions and/or processing information in conjunction with the memory 982.

For communication purposes, the electronic device 902 also includes a modem 994, a wireless transceiver 996, and an antenna (not shown). The wireless transceiver 996 provides connectivity to respective networks and other electronic devices connected therewith using radio-frequency (RF) wireless signals and may include the transceiver circuit 800 of FIG. 8. The wireless transceiver 996 may facilitate communication over any suitable type of wireless network, such as a wireless local area network (LAN) (WLAN), a peer to peer (P2P) network, a mesh network, a cellular network, a wireless wide area network (WWAN), a navigational network (e.g., the Global Positioning System (GPS) of North America or another Global Navigation Satellite System (GNSS)), and/or a wireless personal area network (WPAN).

Implementation examples are described in the following numbered clauses:

1. A BAW resonator, comprising
a piezoelectric material;
a first electrode coupled to the piezoelectric material; and
a second electrode coupled to the piezoelectric material,

wherein
the piezoelectric material is arranged between the first electrode and the second electrode,

wherein the piezoelectric material is LiTaO₃ and has an orientation with Euler angles selected from [0°±5°; 130°±15°; n°±5°], or a symmetrical equivalent, where n is variable.

2. The BAW resonator of clause 1, wherein the Euler angles are selected from [0°±5°; 130°±5°; n°±5°].

3. The BAW resonator of clause 1, wherein the Euler angles are selected from [0°±5°; 130°±15°; 0°±5°].

4. The BAW resonator of any one of clauses 1 to 3, further comprising an acoustic mirror to form an SMR-type resonator.

5. The BAW resonator of any one of clauses 1 to 3, wherein a cavity is defined to form an FBAR-type resonator.

6. The BAW resonator of any of clauses 1-5, having a resonance frequency or an anti-resonance frequency above 3 GHz.

7. The BAW resonator of any one of clauses 1 to 6, where the orientation of the piezoelectric material establishes a longitudinal acoustic wave mode.

8. The BAW resonator of any one of clauses 1 to 7, wherein the piezoelectric material is derived from a wafer and is substantially monocrystalline.

9. The BAW resonator of any one of clauses 1 to 8, further comprising a carrier substrate.

10. The BAW resonator of any one of clauses 1 to 9, wherein the BAW resonator forms a portion of an RF filter circuit.

11. The BAW resonator of clause 10, wherein the RF filter circuit comprises a ladder-type like circuit topology or a lattice-type like circuit topology.

12. A BAW resonator, comprising
a piezoelectric material;
a first electrode coupled to the piezoelectric material; and
a second electrode coupled to the piezoelectric material,

wherein
the piezoelectric material is arranged between the first electrode and the second electrode,

wherein the piezoelectric material is LiTaO₃ and has an orientation with Euler angles selected from at least one of the following:

[0°±5°; 130°±15°; n°±5°] where n is variable; or

[0°±5°; 130+n*180°±15°; n°±5°]; or

[Φ+n*120°±5°, 130°±15, n°±5°]; or

[Φ+n*60°, (−1)\hat{ }n*130°±15, n°±5°].

13. A BAW resonator, comprising:
a piezoelectric material;
a first electrode coupled to the piezoelectric material; and
a second electrode coupled to the piezoelectric material,

wherein
the piezoelectric material is arranged between the first electrode and the second electrode,

wherein the piezoelectric material is LiNbO₃ and has an orientation with Euler angles selected from at least one of the following:

[0°±5°; 130°±3°; n°±5°], where n is variable; or

[0°±5°; 130+n*180°±3°; n°±5°]; or

[Φ+n*120°±5°, 130°±3, n°±5°]; or

[Φ+n*60°, (−1)\hat{ }n*130°±3, n°±5°].

14. The BAW resonator of clause 13 wherein the Euler angles are selected from [0°±5°; 128°; n°±5°].

15. The BAW resonator of clause 13 wherein the Euler angles are selected from [0°±5°; 130°±3°; 0°±5°].

16. The BAW resonator of any one of clauses 13 to 15 further comprising an acoustic mirror to form an SMR-type resonator.

17. The BAW resonator of any one of clauses 13 to 15, wherein a cavity is defined to form an FBAR-type resonator.

18. The BAW resonator of any one of clauses 13 to 17, having a resonance frequency or an anti-resonance frequency above 3 GHz.

19. The BAW resonator of any one of clauses 13 to 18, wherein the piezoelectric material is derived from a wafer and is substantially monocrystalline.

20. The BAW resonator of any one of clauses 13 to 19, further comprising a carrier substrate.

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

By way of example, an element, or any portion of an element, or any combination of elements described herein may be implemented as a “processing system” that includes one or more processors. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, software components, applications, software applications, software packages, routines, subroutines, objects, executables, threads of execution, procedures, functions, etc., whether referred to as software, firmware, middleware, microcode, hardware description language, or otherwise.

Accordingly, in one or more example embodiments, the functions or circuitry blocks described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise a random-access memory (RAM), a read-only memory (ROM), an electrically erasable programmable ROM (EEPROM), optical disk storage, magnetic disk storage, other magnetic storage devices, combinations of the aforementioned types of computer-readable media, or any other medium that can be used to store computer executable code in the form of instructions or data structures that can be accessed by a computer. In some aspects, components described with circuitry may be implemented by hardware, software, or any combination thereof.

Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A BAW resonator, comprising
a piezoelectric material;
a first electrode coupled to the piezoelectric material; and
a second electrode coupled to the piezoelectric material,
wherein
the piezoelectric material is arranged between the first electrode and the second electrode,
wherein the piezoelectric material is LiTaO₃ and has an orientation with Euler angles selected from [0°±5°; 130°±15°; n°±5°], or a symmetrical equivalent, where n is variable.

2. The BAW resonator of claim 1, wherein the Euler angles are selected from [0°±5°; 130°±5°; n°±5°].

3. The BAW resonator of claim 1, wherein the Euler angles are selected from [0°±5°; 130°±15°; 0°±5°].

4. The BAW resonator of claim 1, further comprising an acoustic mirror to form an SMR-type resonator.

5. The BAW resonator of claim 1, wherein a cavity is defined to form an FBAR-type resonator.

6. The BAW resonator of claim 1, having a resonance frequency or an anti-resonance frequency above 3 GHz.

7. The BAW resonator of claim 1, where the orientation of the piezoelectric material establishes a longitudinal acoustic wave mode.

8. The BAW resonator of claim 1, wherein the piezoelectric material is derived from a wafer and is substantially monocrystalline.

9. The BAW resonator of claim 1, further comprising a carrier substrate.

10. The BAW resonator of claim 1, wherein the BAW resonator forms a portion of an RF filter circuit.

11. The BAW resonator of claim 10, wherein the RF filter circuit comprises a ladder-type like circuit topology or a lattice-type like circuit topology.

12. A BAW resonator, comprising
a piezoelectric material;
a first electrode coupled to the piezoelectric material; and
a second electrode coupled to the piezoelectric material,
wherein
the piezoelectric material is arranged between the first electrode and the second electrode,
wherein the piezoelectric material is LiTaO₃ and has an orientation with Euler angles selected from at least one of the following:
[0°±5°; 130°±15°; n°±5°] where n is variable; or
[0°±5°; 130+n*180°±15°; n°±5°]; or
[Φ+n*120°±5°, 130°±15, n°±5°]; or
[Φ+n*60°, (−1)\hat{ }n*130°±15, n°±5°].

13. A BAW resonator, comprising:
a piezoelectric material;
a first electrode coupled to the piezoelectric material; and
a second electrode coupled to the piezoelectric material,
wherein
the piezoelectric material is arranged between the first electrode and the second electrode,
wherein the piezoelectric material is LiNbO₃ and has an orientation with Euler angles selected from at least one of the following:
[0°±5°; 130°±3°; n°±5°], where n is variable; or
[0°±5°; 130+n*180°±3°; n°±5°]; or
[Φ+n*120°±5°, 130°±3, n°±5°]; or
[Φ+n*60°, (−1)\hat{ }n*130°±3, n°±5°].

14. The BAW resonator of claim 13 wherein the Euler angles are selected from [0°±5°; 128°; n°±5°].

15. The BAW resonator of claim 13 wherein the Euler angles are selected from [0°±5°; 130°±3°; 0°±5°].

16. The BAW resonator of claim 13 further comprising an acoustic mirror to form an SMR-type resonator.

17. The BAW resonator of claim 13, wherein a cavity is defined to form an FBAR-type resonator.

18. The BAW resonator of claim 13, having a resonance frequency or an anti-resonance frequency above 3 GHz.

19. The BAW resonator of claim 13, wherein the piezoelectric material is derived from a wafer and is substantially monocrystalline.

20. The BAW resonator of claim 13, further comprising a carrier substrate.
